(19) United States
(12) Patent Application Publication
(10) Pub. No.: US 2007/0105400 A1
(43) Pub. Date: May 10, 2007

(54) Method and apparatus for control of layer thicknesses

(75) Inventors: Bernd Heinz, Buchs (CH); Cem Yavaser, Azmoos (CH); Thomas Pfaff, Buchs SG (CH); Josef Steinkeller, St. Gallen (CH)

Correspondence Address: PEARNE & GORDON LLP, 1801 EAST 9TH STREET, SUITE 1200, CLEVELAND, OH, 44114-3108, US

(73) Assignee: Unaxis Balzers AG, Balzers (LI)

(21) Appl. No.: 11/269,911

(22) Filed: Nov. 8, 2005

(51) Int. Cl. B05C 13/02; H01L 21/31

(52) U.S. Cl. 438/782; 118/52

(57) ABSTRACT

It is shown a method and apparatus for distributing a viscous liquid over a surface of a substrate with high homogeneity in a defined area, e. g. on a semiconductor wafer or a data storage media, by conditioning the liquid on the substrate thermally in a first step and exposing it to UV radiation in two further steps, locally specific before or during the spin coating process.

### FIELD OF THE INVENTION

This invention generally relates to the field of spin coating of substrates, especially to a method and apparatus for controlling the thickness distribution of a coating.

### BACKGROUND OF THE INVENTION

It is well known in the art, especially in the field of semiconductor manufacturing but also in certain areas of optics or biotechnology, to achieve a homogenous distribution of liquids on an essentially plane substrate by rotating (spinning) a substrate around an axis normal to the plane given by its surface. By applying a viscous liquid onto the surface during spinning centrifugal forces affect a distribution of the liquid radially outwards over the surface. Such “spinning” technique is used to disperse e. g. lacquer, resins, photo resist on semiconductor substrates. Moreover it is utilised in the production of optical data storage technology to provide an essentially homogeneous layer of resin, lacquer, adhesive and others. A special case is the production of so called Blu-ray Disks (hereinafter abbreviated BD), which demand for a 100 μm top layer a uniformity of +−1% for major parts of the surface, i. e. the information storage area (Blu-ray Double Layer Disk 75 μm).

A standard process for such distribution method is:
1) Dispensing a liquid on the substrate to be coated; eventually rotating it slowly during this step to achieve a advantageous initial spreading.
2) Spinning the disk at high speed (typically a few hundred rpm up to 12.000 rpm) to homogeneously distribute the liquid. The thickness of the layer then depends on parameters such as viscosity, temperature, rotation speed and rotation time.

Typical values for viscosity of lacquers used for such layers is between 1500 mPas-2000 mPas.

For substrates with a centre hole the profile of the spin coated layer thickness shows a low-high trend from the inner radius towards the outer edge. This is due the fact that there is no liquid material at/close to the centre hole which could flow outwards. This lack of material causes the reduced thickness at small radii.

The variation of the thickness distribution therefore will not be reduced to a minimized level by standard spin coating process. In order to achieve an optimized coating condition, an extra treatment during spin coating process is required.

It is therefore desirable to have a method to influence the radial thickness distribution during the spinning process. The radial thickness dependence of a liquid's thickness is dictated by the physics of the spinning process and cannot be avoided with radially constant viscosity of the liquid. The objective of the invention therefore is to provide a method for controlling the viscosity of the liquid to be distributed during spinning.

Another problem encountered during improvement of radial thickness distribution is the so called “outer edge bump” or “edge bead”. Due to edge effects during spinning the spinned liquid tends to accumulate at the edge of the rotating disc to form a bead. This edge bump has to be removed or avoided.

### DESCRIPTION OF PRIOR ART

PCT publication WO 2004/050261 describes a way to influence the radial thickness distribution by influencing the viscosity of a liquid to be distributed, locally specific. In other words, at certain radii of the spinning substrats the liquid is conditioned by heat or cold to enhance or reduce the viscosity. This allows adjusting the thickness distribution as desired.

WO 2004/064055 adresses the same problem. This document suggests solidifying the liquid by means of UV radiation and applying a temperature profile, which increases from inner radii to outer radii.

### SUMMARY OF THE INVENTION

To influence the liquid's viscosity in a spin coating process, especially the top layer of a Blu-ray Disk, but also in general a resin layer thickness distribution of spin-coated substrates with a centre hole (e.g. optical disks like DVD, CD, . . . ), a essentially three-step process is being proposed, comprising (a) creating a temperature gradient locally selectively before or during a spinning process by a heat source directed to the side of the substrate where the liquid is distributed on, (b) low-intensity UV curing plus subsequent edge cleaning and (c) a final curing step without rotation.

### DETAILED DESCRIPTION OF THE INVENTION

The above mentioned three steps can be described in more detail by the following process steps, which are needed to apply a 100 μm cover layer onto a BD substrate, using a UV curable lacquer:

Step (a)

1.) Applying a viscous, UV-curable liquid, e. g. a lacquer onto a rotating substrate (dispensing step)
2.) Distributing the liquid (spinning step)
3.) Heating the liquid while spinning to achieve a preliminary thickness uniformity
   Step (b)
1.) Rotating said substrate at around 400-1000 rpm and exposing it to UV irradiation of a first intensity, using low UV intensity and thereby leaving the liquid over the whole surface still mobile. “Low intensity” in this respect means 10-100 mW/cm² for a duration of 0.5 to 1.5 s
2.) Rotation at higher speed to adjust the final thickness, the final thickness uniformity and to remove the excess liquid at the outer edge.
   Step (c)
1.) Final curing at a second level of intensity without rotation. UV curing power is several hundred mW/cm² (preferably 400-700 mW/cm²) for 2-3 s.

Optionally Step (a), (b) and (c) can be performed in separate process stations, or steps (a) and (b) can be performed in one station while step (c) takes place separately. In another embodiment steps (b) and (c) may be combined. Depending on cycle times and necessary throughput a man skilled in the art will arrange this accordingly.

In more detail, a substrate such as a BD substrate is placed on a rotatable turntable or a chuck. This substrate usually is made from polycarbonate or another suitable plastic material, the method however is in wider ranges not dependant on the substrate material used. The dispensing takes place by means of a pumping mechanism which is construed to distribute a predetermined amount of viscous liquid, e. g. a lacquer, a resin or adhesive, onto the substrate. Since the substrate has a center hole, distribution preferably is realized in the form of a ring around the center hole. The initial distributing is being achieved by spinning the substrate at a speed of about 100 rpm, depending on the initial viscosity of the liquid.

Then the rotational speed is increased to about 900-1800 rpm and during spinning the liquid is conditioned thermally, e. g. by a stream of hot air, directed at one or more respective radii of the rotating disk, or Infrared (IR)—lamps in order to change the liquid's viscosity over the radius of the disk. With this thermal treatment the liquid layer is being pre-shaped without necessarily achieving the final precision and thickness.

In step (b) the rotating speed of the substrate initially is reduced to a value between 400-1200 rpm, preferably 600 rpm and the substrate is exposed to low-intensity UV, 10-100 mW/cm² for a duration of 0.5 to 1.5 s). This UV exposure allows to partially solidifying the liquid. An outer mask, preferably covering only 1 mm of the outer edge or even less, thus shading the disc from the UV curing, leaves the outer rim of the liquid on the disk less solid than the information storage areas. Such a mask preferably is circular with a diameter of 118-119 mm, such mask arranged approximately a millimeter above the substrate, concentrically with the substrate. Alternatively the mask may be circular with a diameter of less than 118 mm, but eccentrically arranged with respect to the substrate. With the help of adjusting means the eccentricity can be controlled and adjusted.

Inventively therefore the combination mask plus low intensity radiation plus the moderate spinning speed do not result in the buildup of an outer edge bump, as compared to Prior Art. Rather by means of this pre-curing step the viscosity of liquid on the whole disc is increased to such an extent that no liquid will flow outwardly to build the outer edge bump, but still leaves enough mobility of the liquid to homogenize the layer thickness in the subsequent process steps. The very narrow mask during UV curing will prevent the hardening of droplets at the edge, resulting from the spinning.

The subsequent rotation at higher speeds (e. g. 5000 rpm for 0.5 s) removes excess liquid. Moreover, the inventive low intensity UV exposure of 10-100 mW/cm² allows for a significant amount of lacquer (10% of the thickness, 10 μm) to be removed also from the inner part of the disk during the final spinning step. This is the key step to achieve the final precise homogeneity of +−1% and a good cosmetic appearance at the outer edge of the disk.

In step (c) the surface is being UV cured again, however with a level of exposure to solidify the liquid sufficiently to preserve the surface homogeneity, such as several hundred mW/cm² (preferably 400-700 mW/cm²) for 2-3 s.

An apparatus suitable to implement the invention may comprise a rotatable support, dispensing means to spread a liquid on the surface of the substrate and means to fasten at least one thermal source in a position with respect to the substrate, where it can influence the thermal condition of the substrate. Further such apparatus will comprise a source of UV radiation, such as a UV lamp, which may be realized as a continuous radiation or as a flashlight. It may be advantageous to place the lamp in the apparatus above the substrate or remote, e. g. with a fiber wire and respective optical accessories to allow the distribution of UV radiation over the substrate.

In a preferred embodiment the apparatus will be comprise two process stations. The first one will combine dispensing means, thermal conditioning means and a first source of UV radiation to allow performing step (a) and (b) as described above. Afterwards the substrate is transferred to a second process station for the final curing step. This allows choosing a dedicated low intensity UV lamp for the first and a dedicated higher intensity lamp for the second curing step. On the other hand, one can combine steps (b) and (c). Thus the excess lacquer, spinned away during first dispensing step (a) can be reused and will not be polluted by the semi-solidified lacquer spinned away during step (b). Further, the number of UV radiation sources can be reduced to one, provided that the UV source can be dimmed or its intensity can be reduced e. g. by means of filters. Since production lines for optical substrates such as BD, CD or DVD are designed to high-throughput, it may be advantageously to arrange several process stations for this 3-step-process.

### BRIEF DESCRIPTION OF THE DRAWINGS

FIG. 1 is a time diagram showing the processing steps (a) through (c)

FIG. 2 shows an apparatus for performing step (b)

### DETAILED DESCRIPTION OF THE DRAWINGS

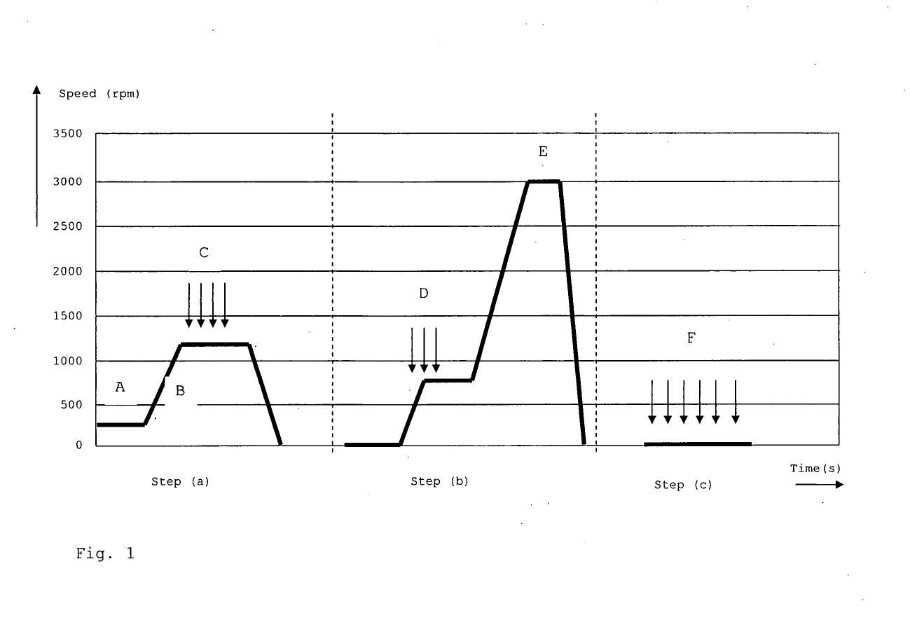

FIG. 1 shows a diagram with the main processing steps (a) to (c). A denotes the dispensing phase, B&C the spinning of the viscous liquid with C denoting the heating time, D means UV exposure, E is the phase of edge cleaning and F denotes the final UV curing step.

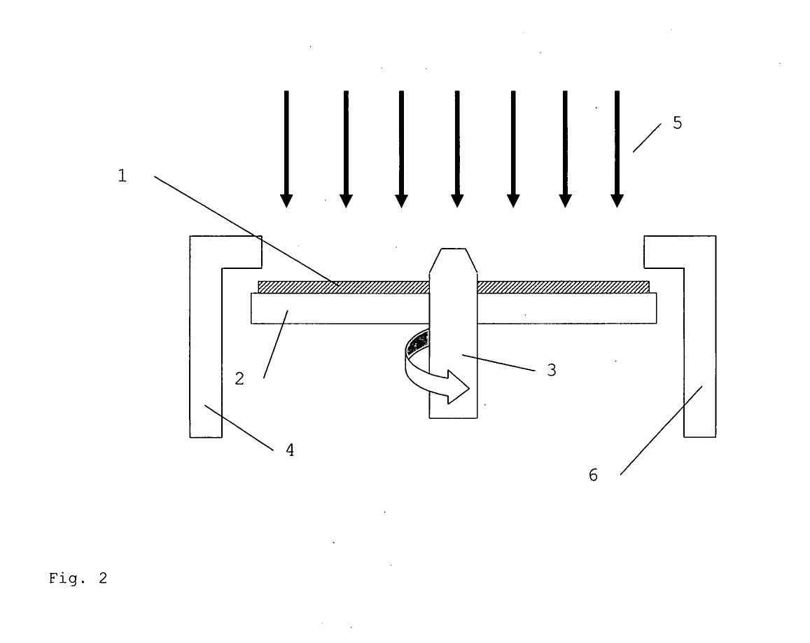

FIG. 2 (not drawn to scale) shows an embodiment suitable for step (b). Substrate 1 is placed on a support 2 and can be rotated around central axis 3. Circular mask 4 is arranged such that the outer rim of substrate 1 is only little affected by UV radiation 5.

What is claimed is:

1. A method for distributing a viscous liquid over a surface of a substrate with high homogeneity in a defined area, comprising the steps:
i. placing a substrate essentially horizontal on a support
ii. applying a viscous, UV curable liquid onto a surface of said substrate
iii. rotating the substrate to distribute the liquid radially outwards and
iv. Conditioning the liquid on the substrate thermally, to influence its viscosity locally in a specific way.
v. Exposing the liquid to UV radiation of a first intensity to partially solidify the liquid
vi. Spinning off excess liquid from the disc
vii. Exposing the liquid to UV radiation of a second intensity to solidify the liquid

2. A method according to claim 1, wherein the thermal conditioning of the liquid takes place by means of a stream of hot air.

3. A method according to claim 1, wherein first intensity of UV radiation equals to 10-100 mW/cm².

4. A method according to claim 1, wherein second intensity of UV radiation means several hundred mW/cm².

5. A method according to claim 1, wherein during thermal conditioning the substrate is rotated at a speed between 400-1200 rpm.

6. A method according to claim 1, wherein during exposure to UV radiation of a first intensity the substrate is rotated at a speed between 400-1000 rpm.

7. A method according to claim 1, wherein steps i) to iv) are performed in one process station.

8. A method according to claim 1, wherein steps vi) and vii) are each performed in separate process stations.

9. Apparatus for distributing a viscous liquid over a surface of a substrate with high homogeneity in a defined area, comprising
A rotatable support
Dispensing means for a liquid to be distributed on the substrate's surface
A thermal source for conditioning the liquid on the substrate thermally, to influence its viscosity locally in a specific way.
A source of UV radiation for exposing the liquid to UV radiation

10. Apparatus according to claim 9, further comprising a mask arranged between substrate (1) and UV radiation (5) such that the outer rim of substrate (1) is only little affected by UV radiation (5).

11. Apparatus according to claim 10, wherein the mask is circular and arranged concentrically with the substrate.

12. Apparatus according to claim 9, wherein the mask is circular and arranged eccentrically to the substrate.

13. Apparatus according to claim 9, wherein the source of UV radiation is adapted to provide UV radiation of first, low intensity and further comprising a further source of UV radiation to provide UV radiation of a higher, second intensity.
